(19) United States
(12) Patent Application Publication
(10) Pub. No.: US 2009/0072251 A1
(43) Pub. Date: Mar. 19, 2009

(54) LED surface-mount device and LED display incorporating such device

(75) Inventors: Alex Chi Keung Chan, Sheung Shui (HK); Xuan Wang, Huzhou City (CN)

Correspondence Address: KOPPEL, PATRICK & HEYBL, 555 ST. CHARLES DRIVE, SUITE 107, THOUSAND OAKS, CA, 91360, US

(73) Assignee: Cotco Luminant Device Limited

(21) Appl. No.: 12/002,410

(22) Filed: Dec. 14, 2007

(30) Foreign Application Priority Data
Sep. 14, 2007 (CN) 200710152109.7

(51) Int. Cl. H01L 33/00

(52) U.S. Cl. 257/89; 257/E33.059

(57) ABSTRACT

In one embodiment, a surface-mount device comprises a casing having opposed, first and second main surfaces, side surfaces, and end surfaces. A lead frame partially encased by the casing comprises (1) an electrically conductive LED chip carrier part having a surface carrying a linear array of three LEDs adapted to be energized to produce in combination a substantially full range of colors, each LED having a first electrical terminal and a second electrical terminal, the first terminal of each of the three LEDs being electrically and thermally coupled to the chip carrying surface of the chip carrier part; and (2) three electrically conductive connection parts separate from the chip carrier part, each of the three connection parts having a connection pad, the second terminal of each of the three LEDs being electrically coupled to the connection pad of a corresponding one of the three connection parts with a single wire bond. The linear array of LEDs extends in a first direction, and each of the chip carrier part and three connection parts has a lead. The leads are disposed in parallel relationship with each other and extend through the end surfaces of the casing in a second direction, the second direction being orthogonal to the first direction. An array of the surface-mount devices may be used in an LED display such as an indoor LED screen.

### FIELD OF THE INVENTION

The present invention relates generally to electronic packaging, and more particularly to surface-mount devices for use in LED displays.

### BACKGROUND

With the advent of LEDs of increased brightness and color fidelity together with improved image processing technology, large format, full color LED video screens became available and are now in common use. Large format LED displays typically comprise a combination of individual LED panels providing image resolutions determined by the distance between adjacent pixels or “pixel pitch”. Outdoor displays that are intended for viewing from greater distances have relatively large pixel pitches and usually comprise discrete LED arrays in which a cluster of individually mounted red, green and blue LEDs are driven to form what appears to the viewer to be a full color pixel. Indoor screens, on the other hand, requiring shorter pixel pitches, for example, as small as 3 mm or less, typically comprise panels carrying red, green and blue LEDs mounted on single SMD chipsets each defining a pixel. The relatively small SMDs are attached to a driver printed circuit board (PCB). Although these displays are viewable across a substantial range of off-axis angles, for example, up to 145° or even greater, there is often a perceptible loss of color fidelity with increasing viewing angle.

It is well-known that surface-mount devices and many other types of electronic packages, whether containing integrated circuits or discrete components such as diodes or power transistors, dissipate sufficient heat to require thermal management. The objective of thermal management in the design of electronic packaging is to maintain the operating temperature of the active circuit or junction side of the component low enough (for example, 110° C. or below) to prevent premature component failure. Various cooling strategies including conduction heat transfer are in common use. One conventional way of implementing conduction heat transfer for dissipating heat in an electronic package is to allow the heat to conduct away along the leads of the device. However, the leads often do not have sufficient mass or exposed surface area to provide effective heat dissipation. For example, high intensity light emitting diodes (LEDs) that emit light principally in the visible part of the electromagnetic spectrum can generate significant amounts of heat that is difficult to dissipate using such conventional techniques.

### SUMMARY OF THE DISCLOSURE

A better understanding of the features and advantages of the present invention will be obtained by reference to the detailed description, below, and the accompanying drawings showing illustrative embodiments utilizing the principles of the invention.

In accordance with one specific, exemplary embodiment, there is provided a lead frame for a surface-mount device, the lead frame comprising an electrically conductive LED chip carrier part having a surface carrying a linear array of three LEDs adapted to be energized to produce in combination a substantially full range of colors. Each LED has a first electrical terminal and a second electrical terminal, the first terminal of each of the three LEDs being electrically and thermally coupled to the chip carrying surface of the chip carrier part. The lead frame further comprises three electrically conductive connection parts separate from the chip carrier part, each of the three connection parts having a connection pad. The second terminal of each of the three LEDs is electrically coupled to the connection pad of a corresponding one of the three connection parts.

In accordance with another aspect of the invention, the linear array of LEDs extends in a first direction. Further, each of the chip carrier and three connection parts has a lead, the leads being disposed in parallel relationship with each other and extending in a second direction, and wherein the second direction is orthogonal to the first direction.

Pursuant to yet another aspect of the invention, the chip carrier part has a lead electrically coupled to the chip carrying surface, the lead having a thickness. The chip carrying surface of the chip carrier part comprises a surface of a thermally conductive body extending in a direction normal to the chip carrying surface, the thermally conductive body having a thickness greater than the thickness of the chip carrier part lead.

Pursuant to another specific, exemplary embodiment, there is provided a surface-mount device, comprising a casing having opposed, first and second main surfaces, opposed side surfaces, and opposed end surfaces, the casing defining a cavity extending into the interior of the casing from the first main surface. The device further comprises a lead frame partially encased by the casing, the lead frame comprising (1) an electrically conductive LED chip carrier part having a surface carrying a linear array of three LEDs adapted to be energized to produce in combination a substantially full range of colors, each LED having a first electrical terminal and a second electrical terminal, the first terminal of each of the three LEDs being electrically and thermally coupled to the chip carrying surface of the chip carrier part; and (2) three electrically conductive connection parts separate from the chip carrier part, each of the three connection parts having a connection pad, the second terminal of each of the three LEDs being electrically coupled to the connection pad of a corresponding one of the three connection parts.

Pursuant to another aspect of the surface-mount device, the linear array of LEDs extends in a first direction. Each of the chip carrier and three connection parts has a lead, the leads being disposed in parallel relationship with each other and extending through the end surfaces of the casing in a second direction, and wherein the second direction is orthogonal to the first direction.

According to another aspect of the device, the chip carrying surface of the chip carrier part comprises a surface of a thermally conductive body extending in a direction normal to the chip carrying surface to a bottom surface of the body exposed through an aperture formed in the second main surface of the casing.

In accordance with yet another specific, exemplary embodiment, there is provided an LED display comprising a substrate carrying an array of surface-mount devices arranged in vertical columns and horizontal rows, each of the SMDs containing a vertically oriented, linear arrangement of three LEDs adapted to be energized to produce in combination a substantially fill range of colors and to define one pixel of the display. Signal processing and LED drive circuitry is electrically connected to selectively energize the array of SMDs for producing visual images on the display. The linear orientation of the LEDs has been found to improve color fidelity over a wide range of viewing angles.

### BRIEF DESCRIPTION OF THE DRAWINGS

The above and other aspects, features, and advantages of the present embodiments will be more apparent from the following more particular description thereof, presented in conjunction with the following drawings wherein:

FIG. 1 is a perspective view of a surface-mount device in accordance with one specific exemplary embodiment;

FIG. 2 is a top plan view of the device shown in FIG. 1;

FIG. 3 is a cross section view of the device of FIG. 1 as seen along the line 3-3 in FIG. 2;

FIG. 4 is a bottom plan view of the device shown in FIG. 1;

FIG. 5 is an end elevation view of the device shown in FIG. 1;

FIG. 6 is a perspective view of a lead frame in accordance with one specific, exemplary embodiment that may be used in the device of FIG. 1;

FIG. 7 is a top plan view of the lead frame shown in FIG. 6;

FIG. 8 is a side elevation view of the lead frame shown in FIG. 6;

FIG. 9 is a cross section view, along the lines of that shown in FIG. 3, of a surface-mount device in accordance with another specific, exemplary embodiment of the invention;

FIG. 10 is a bottom plan view of the device shown in FIG. 9;

FIG. 11 is an end elevation view of the device shown in FIG. 9; and

FIG. 12 is a front elevation view of a portion of an LED display screen incorporating surface-mount devices in accordance with embodiments of the present invention.

### DETAILED DESCRIPTION

The following description presents preferred embodiments of the invention representing the best mode contemplated for practicing the invention. This description is not to be taken in a limiting sense but is made merely for the purpose of describing the general principles of the invention whose scope is defined by the appended claims.

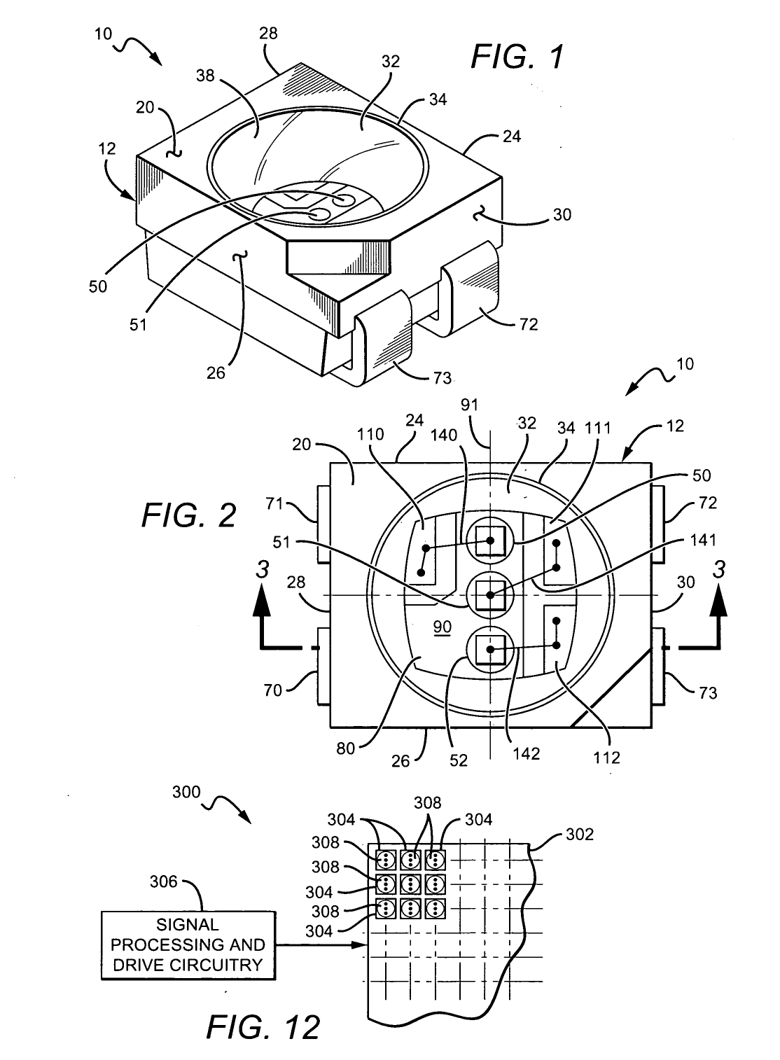

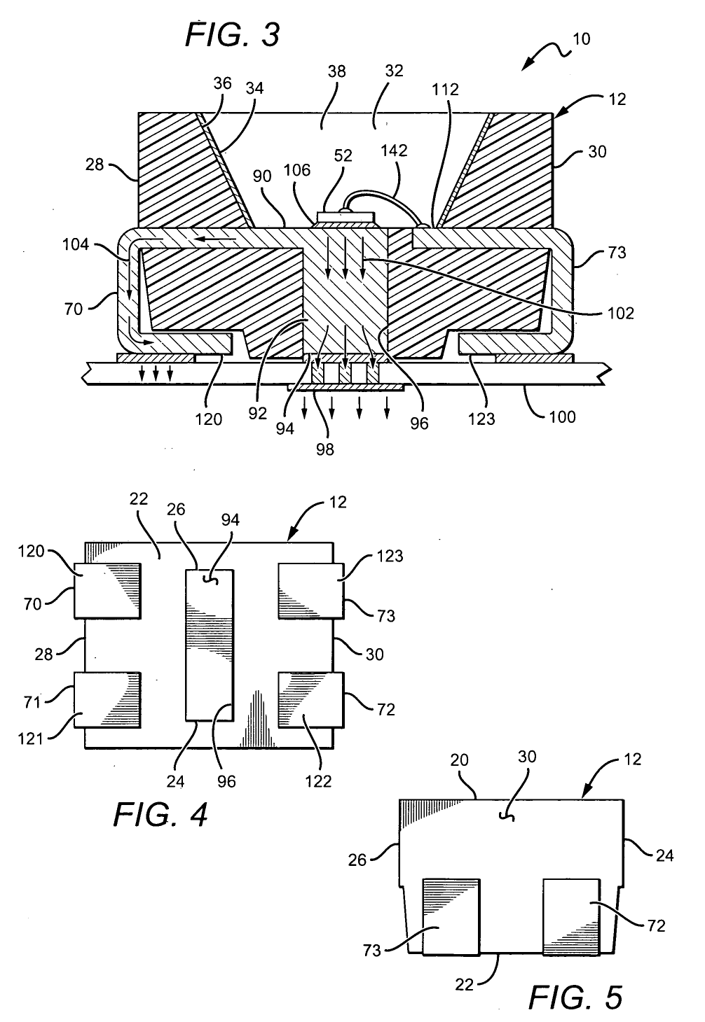

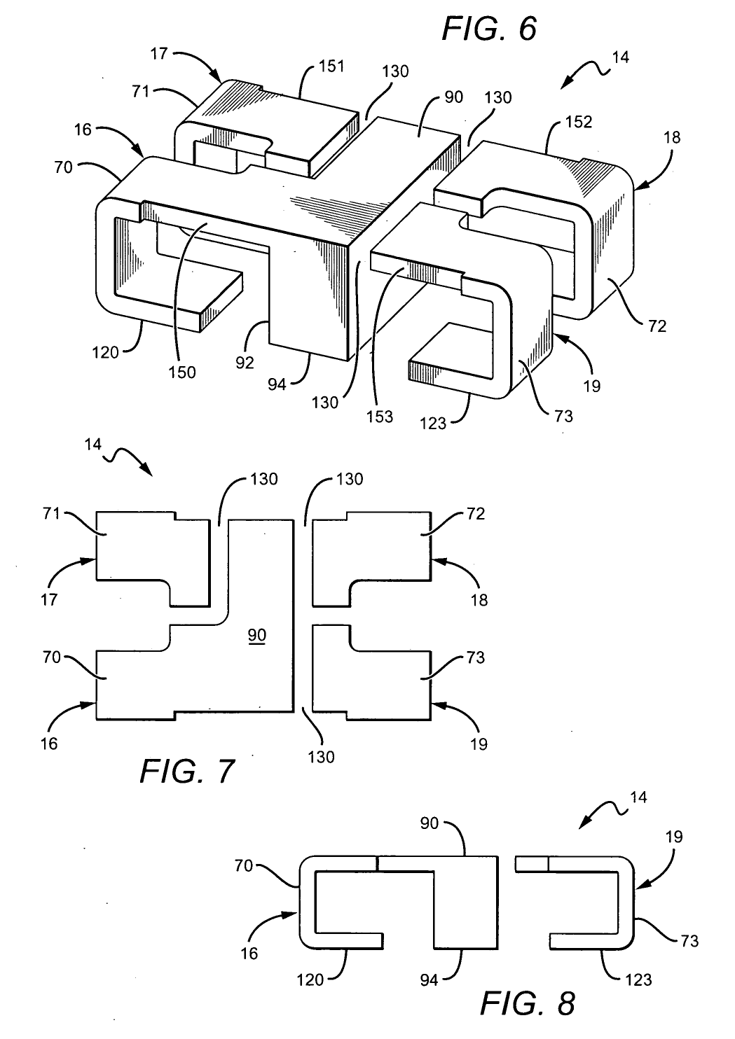

FIGS. 1-8 depict a surface-mount device (SMD) 10 and parts thereof according to specific, exemplary embodiments for use in LED displays such as indoor LED screens. The SMD 10 includes a casing 12 carrying a lead frame 14 comprising a plurality of electrically conductive connection parts, in this example four parts 16-19.

The casing 12 may be generally in the form of a rectangular prism, comprising opposed, parallel upper and lower surfaces 20 and 22, respectively, side surfaces 24 and 26 and end surfaces 28 and 30.

By way of example and not limitation, the SMD 10 may have an overall length of 3.20 mm, an overall width of 2.80 mm, and an overall height of 1.85 mm.

The casing further defines a recess or cavity 32 extending from the upper surface 20 into the body of the casing 12. In some embodiments, a reflective insert or ring 34 may be positioned and secured along at least a portion of a side or wall 36 of the cavity 32, the effectiveness of the reflectivity of the ring 34 preferably being enhanced by tapering the cavity 32 and ring 34 carried therein inwardly toward the interior of the casing.

In some embodiments, the cavity 32 may be at least partially filled with a fill material 38. The fill material 38 can protect and positionally stabilize the lead frame 14 and the LEDs carried thereby. In some instances, the fill material 38 may cover the LEDs, the portions of the lead frame connection parts 16-19 exposed through the cavity 32, and the LEDs' electrical connections. The fill material 38 may be selected to have predetermined optical properties so as to enhance the projection of light from the LEDs. The fill material 38 may be formed from a resin, an epoxy, a thermoplastic polycondensate, glass, and/or other suitable materials or combinations of materials. In some embodiments, materials may be added to the fill material to enhance the emission, absorption and/or dispersion of light to and/or from the LEDs.

The casing 12 may be fabricated of material that is preferably both electrically insulating and thermally conductive. Such materials are well-known in the art and may include, without limitation, certain resins, epoxies, thermoplastic polycondensates (e.g., a polyphthalamide (PPA)), ceramics and glass. In a preferred embodiment, the casing 12 may be formed of a black PPA material. It has been found that the use of black material in image generation SMD packages, such as with SMDs employed in video displays, improves contrast.

In the illustrative embodiment depicted, the SMD 10 houses three LEDs 50-52 preferably emitting red, green and blue colors, respectively, so that when appropriately energized the LEDs produce in combination a substantially full range of colors.

In the illustrative embodiment shown, the lead frame parts 16-19 include leads 70-73, respectively, projecting outwardly through the opposed end surfaces 28 and 30 of the casing 12 from a central region 80 thereof.

The connection part 19 comprises a chip carrier part having an enlarged, central surface or pad 90 for carrying the LED chips 50-52 in a linear array that extends in a transverse direction 91, that is, in a direction perpendicular to the side surfaces 24 and 26. The leads 70-73 are parallel to each other and extend in a direction perpendicular to the direction 91 of the linear LED array. The pad 90 comprises the top surface of a thermally conductive body 92, in the form of, for example, a rectangular block extending vertically through the casing 12 to a bottom surface 94 of the body 92 exposed through an aperture 96 in the lower surface 22 of the casing 12 and disposed substantially flush with the lower surface 22. The bottom surface 94 of the body of the connection part 60 is adapted to be disposed in heat transfer relationship with a heat spreader or dissipator 98 carried by a substrate 100 such as a printed wiring or circuit board. It will be seen that the thermally conductive body 92, given its relatively substantial mass and cross section area normal to the direction of heat flow, serves as an efficient heat sink providing a low thermal resistance path (arrows 102) between the heat-generating LEDs 50-52 carried by the pad 90 and the heat spreader 98. Some heat is also dissipated along the lead 70 (arrow 104). By way of example and not by way of limitation, the thermally conductive body 92 may have a height of 1.0 mm, a width of about 2.20 mm and a length of 0.65 mm.

The remaining connection parts 17-19 include enlarged electrical connection pads 110-112, respectively, positioned in the central region 80 adjacent to, but spaced apart from, the component-carrying surface 90 of the connection part 16. In a preferred form of the SMD 10, the leads 70-73 are bent orthogonally to extend outside of and along their respective end surfaces 28 and 30 of the casing, then bent orthogonally again so that end portions 120-123 of the leads extend along the lower surface 22 of the casing 12. The outwardly facing surfaces of the end portions 120-123 of the leads and the bottom surface 94 of the thermal conductive body 92 are substantially flush to facilitate connection to the underlying substrate 100. The end portions 120-123 of the leads are electrically connected or bonded to traces or pads on the substrate 100 using any of a number of well-known connection techniques. As best seen in FIGS. 1-3, the cavity 32 extends into the casing interior a sufficient depth to expose the connection part pads 90 and 110-112.

The dimensions of the end portions 120-123 of the leads 70-73 that extend inwardly from the end surfaces 28 and 30 of the casing may depend on the intended implementation of the SMD, the LEDs to be utilized, the material of the casing 12, the size of the SMD and/or other such factors and/or combinations of factors. For example, in some implementations the width of each of the leads 70-73 exterior of the casing may be about 0.75 mm with a thickness of between about 0.15 and 0.20 mm, and may be separated by gaps 130 between pads of, for example, about 0.20 mm to electrically isolate the connection parts 60-63 from each other.

The connector parts 16-19 may be made from an electrically conductive metal or metal alloy, such as copper, a copper alloy, and/or other suitable low resistivity, corrosion resistant materials or combinations of materials. As noted, the thermal conductivity of the lead 70 of the connector part 16 may assist, to some extent, in conducting heat away from the LEDs 50-52 carried by the SMD as shown by the arrow 104.

Each of the LEDs 50-52 has a pair of electrical terminals or electrodes, identified as a cathode and an anode as is well known. In accordance with a typical implementation of the embodiments shown, the cathodes of the LEDs 50-52 are coupled to the central pad 90 while the anodes of the LEDs are coupled, respectively, to the pads 110-112 of the separate connector parts 61-63 by single wire bonds 140-142.

Each of the LEDs 50-52 may be electrically coupled with the pad 90 by means of an electrically and thermally conductive interface 106 such as an adhesive, coating, film, encapsulant, solder, paste, grease and/or other suitable material. For example, the LEDs may be electrically coupled and secured to the pad 90 by solder bumps or baked silver epoxy.

In other embodiments, one or more of the leads 70-73 may further include one or more indentations, through-holes or apertures, extensions, and/or other features that contribute to the stability, integrity and/or robustness of the SMD package. For example, the leads 70-73 may include indentations 150-153, respectively, that extend generally along the outside edges of the leads. The indentations and/or other such features of the leads cooperate with the casing and/or fill material, at least in part, to enhance the structural stability and integrity of the SMD package. In some implementations, the casing material and/or fill material extends at least partially around, into and/or through one or more of the gaps 130, and areas exposed by the indentations 150-153 formed in the leads.

The SMD 10 may be formed and/or assembled through any one of a variety of known methods. For example, the casing 12 may be formed or molded around the connection parts 16-19. Alternatively, the casing may be molded in sections, for example, top and bottom sections which are subsequently joined by an epoxy, adhesive or other suitable joinder material.

In some methods of manufacturing, the LEDs may be coupled to the pad 90 prior to molding and/or assembling the casing 12 about the connection pads. Alternatively, the LEDs may be coupled to the pad 90 after the connector parts have been partially encased within the casing. The cavity 32 that extends into the casing may be configured so that sufficient portions of the pads 90 and 110-112 are exposed to receive the LEDs and the associated wire bonds.

The fabrication of the connector parts 16-19 may be accomplished by stamping, injection molding, cutting, etching, bending or through other known methods and/or combinations of methods to achieve the desired configurations. For example, the connector parts can be partially metal stamped (e.g., stamped simultaneously from a single sheet of relevant material), appropriately bent, and finally fully separated or fully separated following the formation of some or all of the casing.

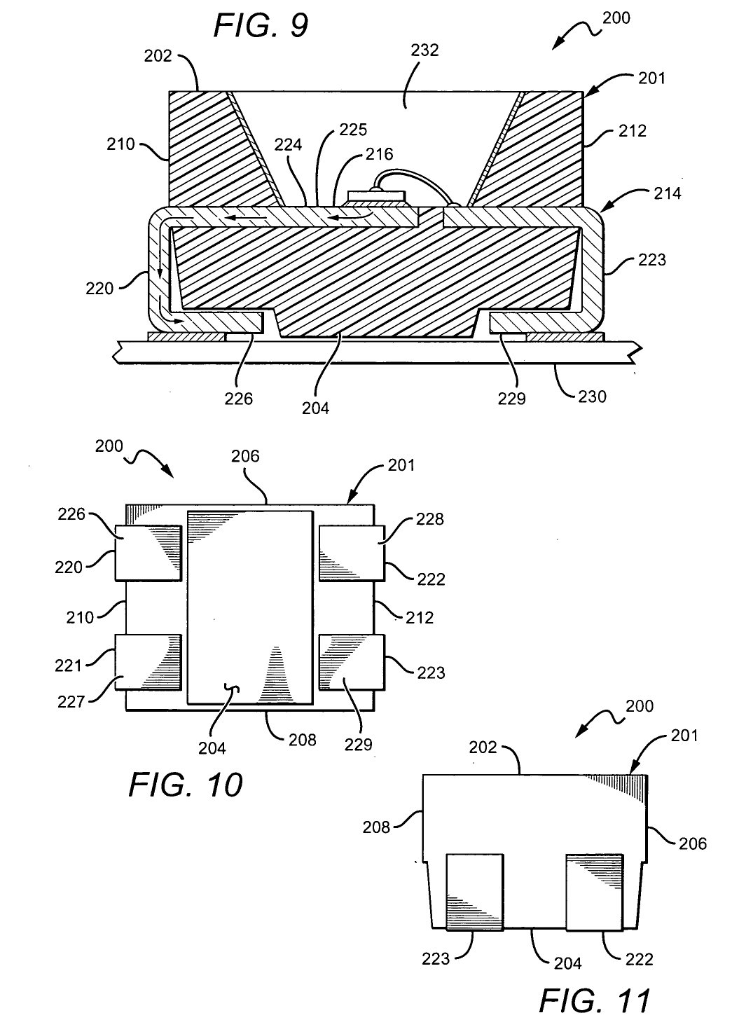

FIGS. 9-11 show a surface-mount device 200 according to another specific, exemplary embodiment for use, by way of example, in an LED display screen. The SMD 200 of FIGS. 9-11 is identical in all respects to the embodiment shown in FIGS. 1-8 except that the thermally conductive body 92 has been omitted. Accordingly, the SMD of FIGS. 9-11 comprises a preferably black casing 201 comprising opposed upper and lower surfaces 202, 204, side surfaces 206, 208 and end surfaces 210, 212. The SMD 200 carries a lead frame 214 comprising, as before, four electrical connection parts that include a chip carrier part 216 and three separate connection parts (including the part 218) and leads 220-223, respectively, projecting outwardly through the opposed end surfaces 210, 212 of the casing from a central region 224 thereof. The chip carrier part 216 has an enlarged, central surface or pad 225 for receiving LED chips, typically comprising red, green and blue LEDs. As before, the remaining connection parts include enlarged wire bond pads positioned in the central region adjacent to, but spaced apart from, the chip carrier part 216.

As before, the leads 220-223 are bent orthogonally to extend along and outside of their respective casing end surfaces, then bent orthogonally again so that end portions 226-229 of the leads 220-223 extend along the bottom surface 204 of the casing. The outwardly facing surfaces of the end portions 226-229 of the leads are electrically connected or bonded to traces or pads on a substrate 230, typically a printed circuit board, using any of a number of well known connection techniques. As before, the casing has a cavity 232 that extends a sufficient depth to expose the pads of the connection parts. The connection parts are preferably made from an electrically conductive sheet metal or sheet metal alloy cut from sheet metal stock by means of punch press operations and then bent into their final configuration either before or after the formation of the casing about the lead frame.

Each of the LEDs has a pair of electrical terminals or electrodes, the cathodes of which are electrically coupled to the central pad 225 while the anodes of the LEDs are coupled, respectively, to the pads of the separate connection parts by single wire bonds.

With reference now to FIG. 12, there is shown in schematic form a portion of an LED display screen 300, for example, an indoor screen comprising, in general terms, a driver PCB 302 carrying a large number of surface-mount devices 304 arranged in rows and columns, each SMD defining a pixel. The SMDs 304 may comprise devices such as the embodiments shown in FIGS. 1-8 and 9-11. The SMD devices 304 are electrically connected to traces or pads on the PCB 302 connected to respond to appropriate electrical signal processing and driver circuitry 306.

As disclosed above, each of the SMDs carries a vertically oriented, linear array 308 of red, green and blue LEDs. Such a linear orientation of the LEDs has been found to improve color fidelity over a wide range of viewing angles.

While several illustrative embodiments of the invention have been shown and described, numerous variations and alternate embodiments will occur to those skilled in the art. Such variations and alternate embodiments are contemplated, and can be made without departing from the spirit and scope of the invention as defined in the appended claims.

We claim:

1. A lead frame for a surface-mount device, the lead frame comprising:
an electrically conductive LED chip carrier part having a surface carrying a linear array of three LEDs adapted to be energized to produce in combination a substantially full range of colors, each LED having a first electrical terminal and a second electrical terminal, the first terminal of each of the three LEDs being electrically and thermally coupled to said chip carrying surface of said chip carrier part;
three electrically conductive connection parts separate from said chip carrier part, each of said three connection parts having a connection pad; and
the second terminal of each of said three LEDs being electrically coupled to the connection pad of a corresponding one of said three connection parts.

2. The lead frame of claim 1 wherein:
the first and second electrical terminals of each of said LEDs comprise a cathode and an anode, respectively.

3. The lead frame of claim 1 wherein:
the linear array of LEDs extends in a first direction; and
each of said chip carrier part and three connection parts has a lead, said leads being disposed in parallel relationship with each other and extending in a second direction, and wherein said second direction is orthogonal to said first direction.

4. The lead frame of claim 1 wherein:
the chip carrier part and the three connection parts are made of sheet metal.

5. The lead frame of claim 1 wherein:
said chip carrier part has a lead electrically coupled to said chip carrying surface, said lead having a thickness; and
the chip carrying surface of the chip carrier part comprising a surface of a thermally conductive body extending in a direction normal to said chip carrying surface, said thermally conductive body having a thickness greater than the thickness of said chip carrier part lead.

6. The lead frame of claim 1 wherein:
the three LEDs comprise a red, a green, and a blue LED.

7. The lead frame of claim 1 wherein:
the second electrical terminal of each of said LEDs is electrically coupled to the connection pad of the associated connection part by means of a single wire bond.

8. A surface-mount device, comprising:
a casing comprising opposed, first and second main surfaces, opposed side surfaces, and opposed end surfaces, the casing defining a cavity extending into the interior of the casing from the first main surface; and
a lead frame partially encased by the casing, the lead frame comprising;
an electrically conductive LED chip carrier part having a surface carrying a linear array of three LEDs adapted to be energized to produce in combination a substantially full range of colors, each LED having a first electrical terminal and a second electrical terminal, the first terminal of each of the three LEDs being electrically and thermally coupled to said chip carrying surface of said chip carrier part;
three electrically conductive connection parts separate from said chip carrier part, each of said three connection parts having a connection pad; and
the second terminal of each of said three LEDs being electrically coupled to the connection pad of a corresponding one of said three connection parts.

9. The device of claim 8 wherein:
the first and second electrical terminals of each of said LEDs comprise a cathode and an anode, respectively.

10. The device of claim 8 wherein:
the linear array of LEDs extends in a first direction; and
each of said chip carrier and three connection parts has a lead, said leads being disposed in parallel relationship with each other and extending through the end surfaces of the casing in a second direction, and wherein said second direction is orthogonal to said first direction.

11. The device of claim 8 wherein:
the chip carrier part and the three connection parts are made of sheet metal.

12. The device of claim 8 wherein:
the chip carrying surface of the chip carrier part comprises a surface of a thermally conductive body extending in a direction normal to said chip carrying surface to a bottom surface of the body exposed through an aperture formed in the second main surface of the casing.

13. The device of claim 8 wherein:
the three LEDs comprise a red, a green, and a blue LED.

14. The device of claim 8 wherein:
the second electrical terminal of each of said LEDs is electrically coupled to the connection pad of the associated connection part by means of a single wire bond.

15. The device of claim 8 wherein:
the casing has a black color.

16. An LED display comprising:
a substrate carrying an array of surface-mount devices arranged in vertical columns and horizontal rows, each of said SMDs containing a vertically oriented, linear arrangement of three LEDs adapted to be energized to produce in combination a substantially fill range of colors and to define one pixel of the display; and
signal processing and LED drive circuitry electrically connected to selectively energize said array of SMDs for producing visual images on said display.

17. The display of claim 8 wherein:
each SMD includes a casing having a black color.
